(19) United States
(12) Patent Application Publication
(10) Pub. No.: US 2026/0304939 A1
(43) Pub. Date: Oct. 1, 2026

(54) BACKSIDE CONTACT WITH EPITAXIAL LINER

(71) Applicant: International Business Machines Corporation, Armonk, NY (US)

(72) Inventors: Kishore Natarajan, Albany, NY (US); Ruilong Xie, Niskayuna, NY (US); Huimei Zhou, Albany, NY (US); Thanh Nguyen, Troy, NY (US); Eunsoo Cho, Albany, NY (US); Oleg Gluschenkov, Tannersville, NY (US)

(21) Appl. No.: 19/091,917

(22) Filed: Mar. 27, 2025

(51) Int. Cl. H10D 84/85; H10D 30/01; H10D 30/43; H10D 62/10; H10D 62/832; H10D 62/834; H10D 64/23; H10D 64/62; H10D 84/01

(52) U.S. Cl. CPC H10D 84/851; H10D 30/014; H10D 30/019; H10D 30/43; H10D 62/121; H10D 62/832; H10D 62/834; H10D 64/256; H10D 64/62; H10D 84/0186; H10D 84/856

(57) ABSTRACT

Embodiments relate to low resistance backside contact with an epitaxial liner. An aspect includes a semiconductor structure having a first transistor including first channels and a first source/drain region and a second transistor including second channels and second source/drain region, the first and second channels being over a bottom dielectric isolation layer. The first source/drain region and the second source/drain region extend beyond a bottom surface of the bottom dielectric isolation layer. A trench-shaped epitaxial liner is formed on the first source/drain region. Backside conductive material is formed in the trench-shaped epitaxial liner.

### BACKGROUND

The present invention generally relates to fabrication methods and resulting structures for integrated circuits (ICs), and more specifically, to fabrication methods and resulting structures configured and arranged to provide a low-resistance backside contact with a concave epitaxial liner.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device for advanced integrated circuit products is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present invention are directed to providing a low resistance backside contact with a concave or convex epitaxial liner. A semiconductor structure includes a first transistor having first channels and a first source/drain region and a second transistor having second channels and a second source/drain region, the first and second channels being over a bottom dielectric isolation layer. The first source/drain region and the second source/drain region extend beyond a bottom surface of the bottom dielectric isolation layer. The semiconductor structure includes a trench-shaped epitaxial liner formed on the first source/drain region and backside conductive material formed in the trench-shaped epitaxial liner.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A, 1B, and 1C respectively depict a top view and cross-sectional views of a portion of an integrated circuit (IC) under-fabrication after fabrication operations according to one or more embodiments;

FIGS. 2A and 2B depict cross-sectional views of a portion of an IC under-fabrication after fabrication operations according to one or more embodiments;

FIGS. 3A and 3B depict cross-sectional views of a portion of an IC under-fabrication after fabrication operations according to one or more embodiments;

FIGS. 4A and 4B depict cross-sectional views of a portion of an IC under-fabrication after fabrication operations according to one or more embodiments;

FIGS. 5A and 5B depict cross-sectional views of a portion of an IC under-fabrication after fabrication operations according to one or more embodiments;

FIGS. 6A and 6B depict cross-sectional views of a portion of an IC under-fabrication after fabrication operations according to one or more embodiments;

FIGS. 7A and 7B depict cross-sectional views of optional stages for epitaxial layer formation for an IC under-fabrication after fabrication operations according to one or more embodiments;

FIGS. 8A and 8B depict cross-sectional views of optional stages for epitaxial layer formation for an IC under-fabrication after fabrication operations according to one or more embodiments;

FIGS. 9A and 9B depict cross-sectional views of a portion of an IC under-fabrication after fabrication operations according to one or more embodiments;

FIGS. 10A and 10B depict cross-sectional views of an option for an IC under-fabrication after fabrication operations according to one or more embodiments;

FIGS. 11A and 11B depict cross-sectional views of a portion of an IC under-fabrication after fabrication operations according to one or more embodiments;

FIGS. 12A and 12B depict cross-sectional views of a portion of an IC under-fabrication after fabrication operations according to one or more embodiments;

FIGS. 13A and 13B depict cross-sectional views of a portion of an IC under-fabrication after fabrication operations according to one or more embodiments;

FIGS. 14A and 14B depict cross-sectional views of a portion of an IC under-fabrication after fabrication operations according to one or more embodiments;

FIGS. 15A and 15B depict cross-sectional views of a portion of an IC under-fabrication after fabrication operations according to one or more embodiments;

FIGS. 16A and 16B depict cross-sectional views of a portion of an IC under-fabrication after fabrication operations according to one or more embodiments;

FIGS. 17A and 17B depict cross-sectional views of a portion of an IC under-fabrication after fabrication operations according to one or more embodiments;

FIGS. 18A and 18B depict cross-sectional views of a portion of an IC under-fabrication after fabrication operations according to one or more embodiments;

FIGS. 19A and 19B depict cross-sectional views of a portion of an IC under-fabrication after fabrication operations according to one or more embodiments; and

FIG. 20 depicts a flowchart of a method of forming a semiconductor structure according to one or more embodiments.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The nanowire or nanosheet MOSFET is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure. The nanowire/nanosheet MOSFET device mitigates the effects of short channels and reduces the drain-induced barrier.

The GAA nanosheet FET structures can provide superior electrostatics. In contrast to known Fin-type FET (FinFET) structures in which the fin element of the transistor extends “up” out of the transistor, nanosheet FET designs implement the fin as a silicon nanosheet/nanowire. In a known configuration of a GAA nanosheet FET, a relatively small FET footprint is provided by forming the channel region as a series of nanosheets (e.g., silicon nanowires). A GAA configuration includes a source region, a drain region, and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized.

Current fabrication methods for ICs may face issues in achieving efficient backside contacts and isolation. In the field of semiconductor devices, the formation of low-resistance backside contacts presents a challenge. The desire for efficient electrical connections in increasingly compact device architectures has driven the development of various techniques to reduce contact resistance. However, existing methods often face limitations, particularly when encountering small pitch patterns (contacted poly pitch (CPP)). Further, the use of high thermal anneal processes can lead to back-end-of-line (BEOL) degradation, which is undesirable for maintaining device integrity.

Previous solutions have attempted to address these issues through various approaches, such as the integration of backside power grids and direct backside contacts. However, these methods often require complex processing steps and may not be compatible with the thermal budgets necessary to prevent frontside interconnect degradation. For instance, while some techniques allow for high-temperature anneals, they are typically constrained by the need to avoid damage to copper-containing interconnects, which limit their applicability in advanced semiconductor manufacturing.

According to one or more embodiments, the present disclosure provides an innovative approach to these challenges by introducing a low-resistance backside contact structure that does not rely on placeholder modules and is compatible with BEOL thermal budgets. A placeholder module can be used to define or protect a specific area of the semiconductor wafer until the backside contact formation is ready to proceed, after removing the placeholder module particularly in complex device architectures with small pitch patterns. According to one or more embodiments, an approach features an epitaxial liner design that enhances the electrical connection between the silicide and the semiconductor material of the source/drain regions, thereby reducing contact resistance and not requiring a placeholder module. By optimizing the epitaxial growth process and utilizing specific crystallographic orientations, the present disclosure achieves a conformal epitaxial liner with improved dopant activation, resulting in a more efficient and reliable direct backside contact. This method not only addresses the limitations of existing technologies but also offers a scalable solution for future technology nodes.

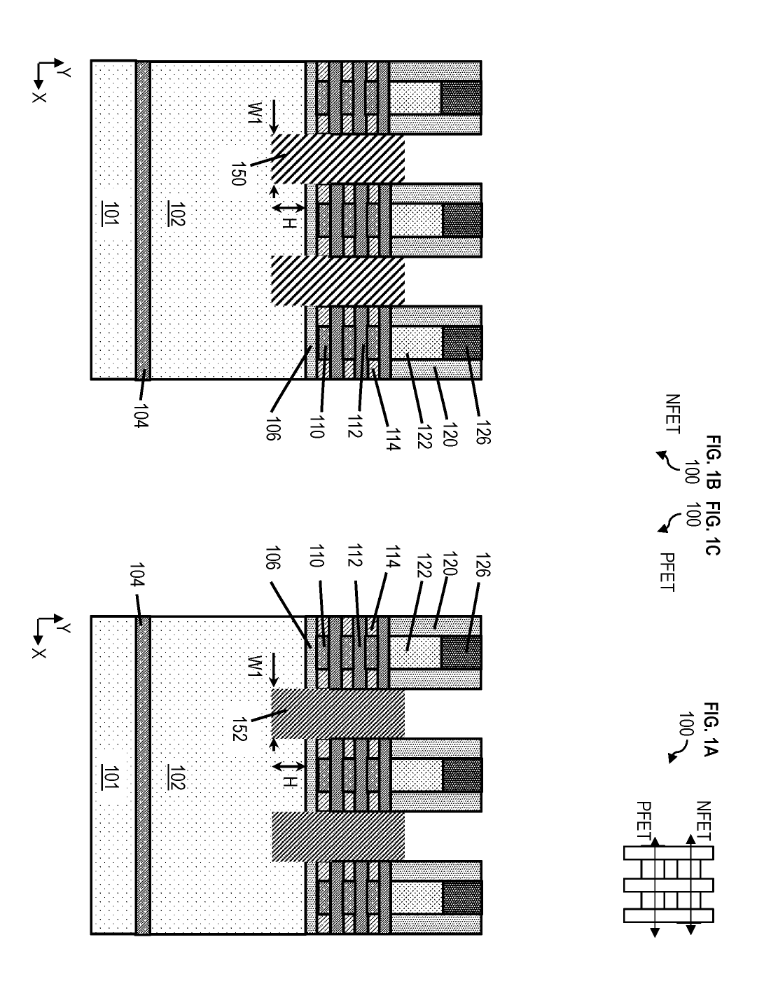

Turning now to a more detailed description of aspects of the present invention, FIG. 1A depicts a top view of a simplified illustration of a portion of an integrated circuit (IC) 100, FIG. 1B depicts a cross-sectional view taken along the NFET of the IC 100, and FIG. 1C depicts a cross-sectional view taken along the PFET of the IC 100. For ease of understanding, some layers may be omitted from the top view so as not to obscure the figure and to view layers underneath. The top view is intended to provide a simplified illustration and a general orientation, but the top view is not intended to be a complete representation of the device. Future locations of layers may be depicted in the top view to assist the reader. Standard semiconductor fabrication techniques can be utilized to fabricate the IC 100 as understood by one of ordinary skill in the art. Any suitable lithography processes including deposition techniques and etching techniques can be utilized herein.

FIGS. 1B and 1C depict the IC 100 having a wafer where several known fabrication processes have been performed. A substrate 102 is over a lower substrate 101 with an (intervening) etch stop layer 104 in between. The substrate 102, lower substrate 101, and semiconductor layers 112 may be formed of silicon or other semiconductor materials. There are alternating nanosheets of semiconductor layers 112 and sacrificial layers 110 formed over the substrate 102. The semiconductor layers 112 are channel regions for the transistor. The sacrificial layers 110 and etch stop layer 104 are formed of silicon germanium (SiGe). Inner spacers 114 separate the semiconductor layers 112, and a bottom dielectric isolation layer 106 separates the substrate 102 from the inner spacers 114 and sacrificial layers 110. Gate spacers 120 are on the sides of dummy gate 122, and a hard mask layer 126 is formed on top of the dummy gate 122. The dummy gate 122 can be formed of amorphous silicon, polysilicon, etc. The inner spacers 114, bottom dielectric isolation layer 106, and gate spacers 120 can be formed of dielectric materials appropriate for selective etching. The hard mask layer 126 can be formed of a dielectric material appropriate for selective etching. The dielectric materials can include low-k dielectric materials, ultra-low-k dielectric materials, etc. The dielectric materials can include oxide-based materials, nitride-based materials, etc.

In FIG. 1B, source/drain regions 150 are formed and are doped with n-type dopants for the NFET. In FIG. 1C, source/drain regions 152 are formed and are doped with p-type dopants for the PFET. The source/drain regions 150 and 152 extend a height H or distance in the y-axis below the bottom surface of the bottom dielectric isolation layer 106. The source/drain regions 150 and 152 have a width W1 in the x-axis.

In one or more embodiments, the source/drain regions can be highly-doped source/drain regions with a chemical concentration of dopants above 5x10²⁰ cm⁻³ extends into a low-doped well/substrate with a chemical concentration of dopants below 5x10¹⁹ cm⁻³. In one or more embodiments, the amount of source/drain extension of height/distance H may range from about 0 nanometers (nm) to 50 nm in the y-axis. The extension with height H can be the same or different for the NFET and PFET. In one or more embodiments, the width W1 may range from about 10 nm to 100 nm in the x-axis. Generally, according to one or more embodiments, the doping polarity of the substrate/well (in the substrate 102) is opposite to that of source/drain regions 150 and 152, where the substrate/well is p-type for NEFT and the substrate/well is n-type for PFET. However, in some embodiments, the doping polarity of the substrate/well can be either the same or opposite to that of respective source/drain regions 150 and 152. It is noted that the well or well material refers to a portion of the substrate that has been doped with p-type dopants or n-type dopants.

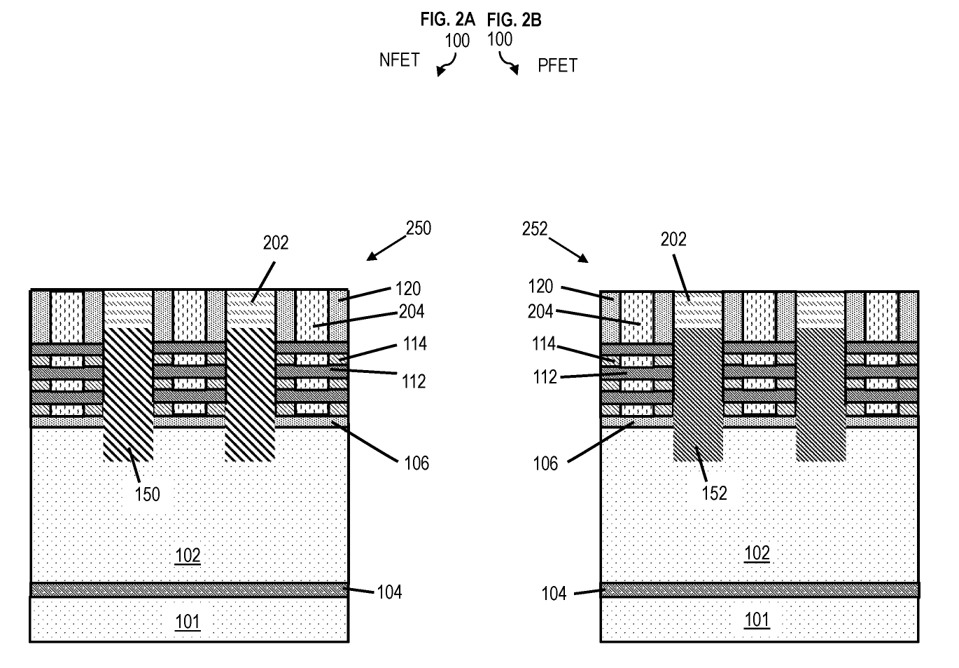

FIGS. 2A and 2B depict the IC 100 after interlayer/intralayer dielectric (ILD) layer deposition and replacement metal gate (RMG) formation. The ILD layer 202 is formed over the source/drain regions 150 and 152 in preparation for the RMG process. The RMG process includes removing the hard mask layer 126, removing the dummy gate 122 (e.g., polysilicon pull and channel release), and forming a high-k dielectric layer and work function material as a gate structure 204. The gate structure 204 may be referred to as a high-k metal gate or high-k metal gate stack (HKMG).

As can be seen, the NFET is transistor 250 that includes the gate structure 204, the semiconductor layers 112 as channels, and the source/drain regions 150. The PFET is transistor 252 that includes the gate structure 204, the semiconductor layers 112 as channels, and the source/drain regions 152. In one or more embodiments, the transistors 250 and 252 may be adjacent transistors and concurrently formed to be complementary. In one or more embodiments, the transistors 250 and 252 may be a distance apart from each other on the wafer.

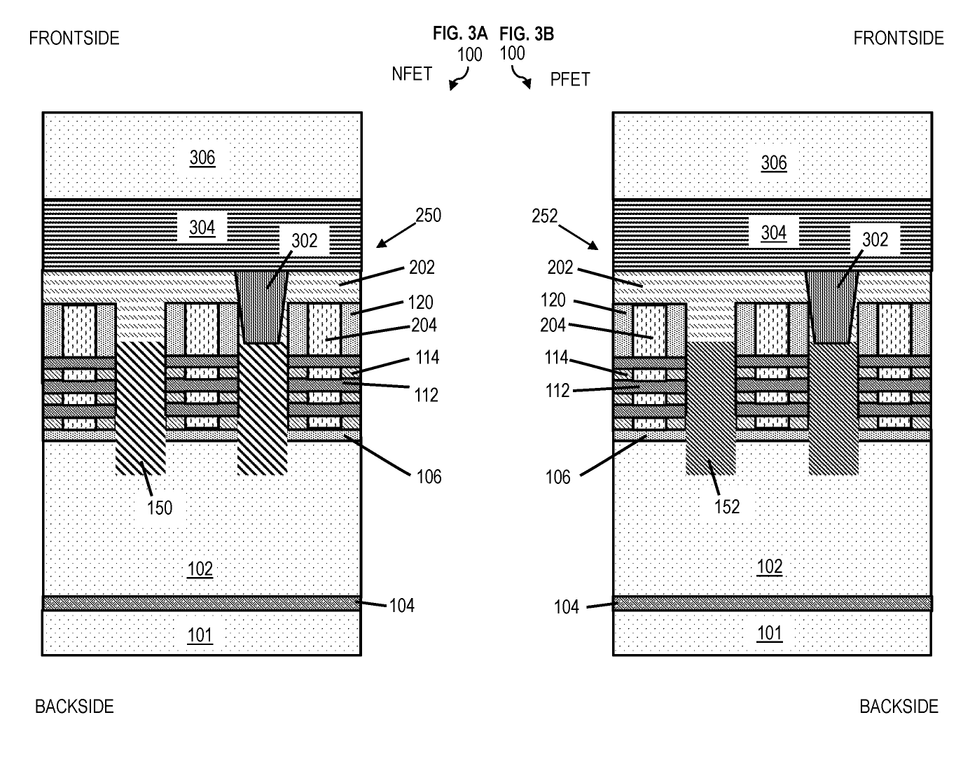

FIGS. 3A and 3B depict the IC 100 after contact formation, back-of-line (BEOL) formation, and carrier wafer bonding. Lithography is performed to form cavities, and conductive material is deposited in the cavities to form frontside source/drain contacts 302. Example conductive materials of the contacts can include tungsten, titanium, titanium nitride, aluminum, nickel, chromium, copper, gold, etc., along with various combinations and liners.

BEOL processing can be performed to form a frontside interconnect layer 304, and a carrier wafer 306 is bonded on the frontside interconnect layer 304 in preparation for wafer flip. The frontside interconnect layer 304 may represent many layers, interconnects, insulating material, etc.

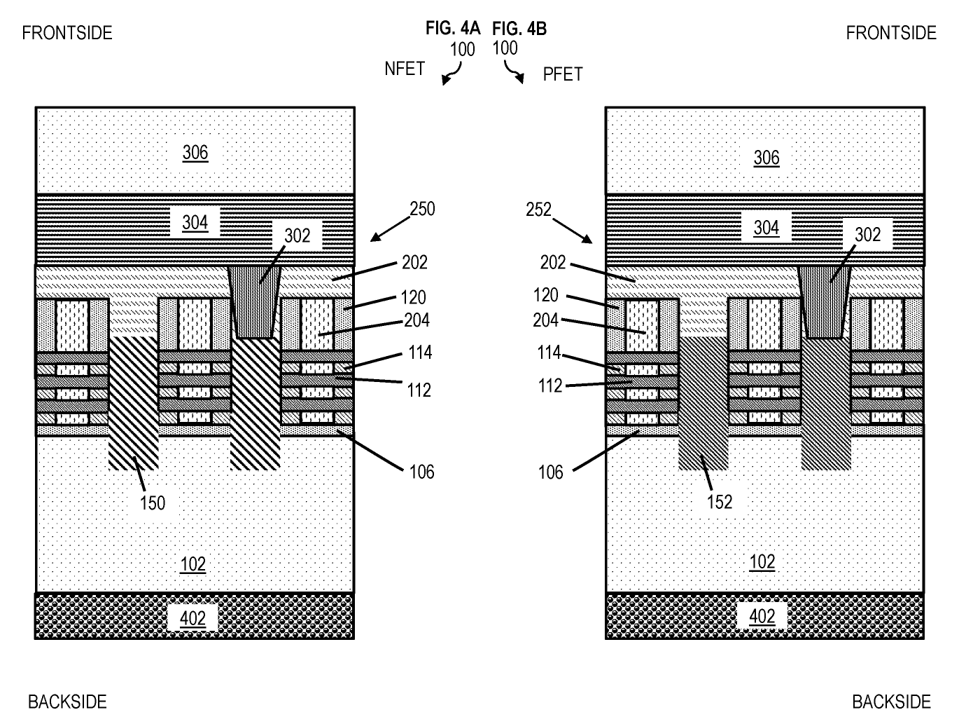

FIGS. 4A and 4B depict the IC 100 after wafer flip and removal of the lower substrate and etch stop layer. The wafer is flipped, and processing continues on the backside of the semiconductor structure. For consistency and to assist the reader, the wafer is not illustrated as being flipped in the figures, although it is understood that the wafer is flipped with fabrication processing performed on the backside.

The lower substrate 101 is removed to expose the etch stop layer 104. Etching and/or chemical mechanical polishing/planarization (CMP) may be utilized to remove the lower substrate 101. Etching can be performed to further remove the etch stop layer 104. A dielectric cap layer 402 is deposited on the exposed surface of the substrate 102. The dielectric cap layer 402 can be a dielectric material such as silicon nitride (SiN) or other materials. The dielectric cap layer 402 can serve as a hard mask layer to protect the substrate 102 during subsequent fabrication processes.

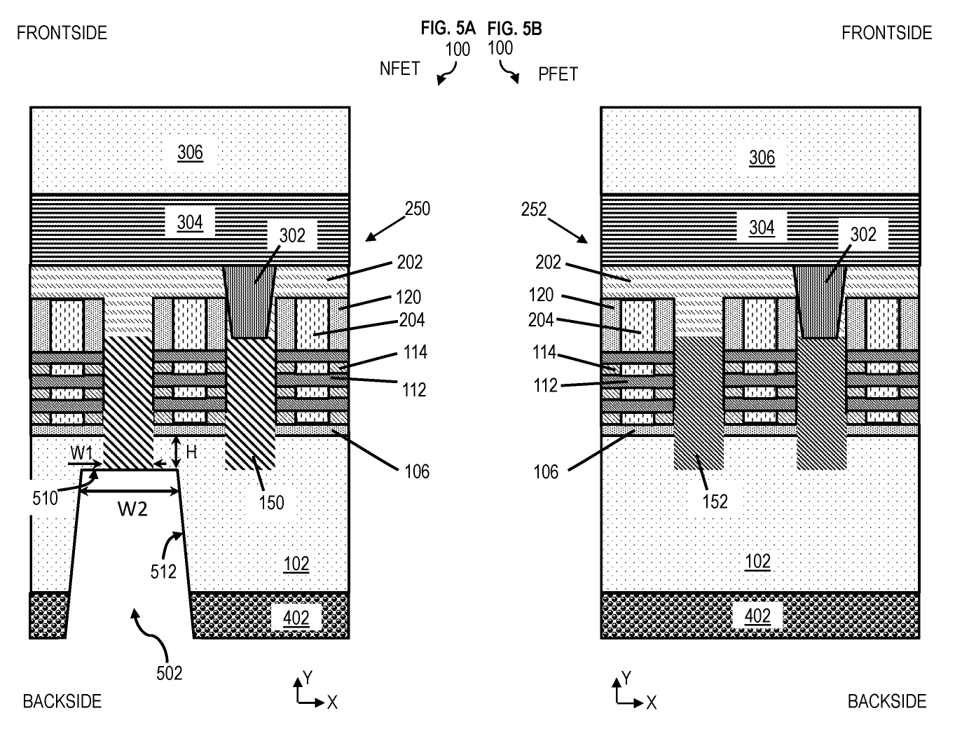

FIGS. 5A and 5B depict the IC 100 after preparation for NFET contact formation on the NFET side while the PFET side is protected by the hard mask layer. Etching is performed to pattern the dielectric cap layer 402. For example, a block mask can be formed and patterned, and the patterned block mask can be utilized to etch the dielectric cap layer 402. Example materials for the block mask can include photoresist materials, silicon-containing antireflective coating (SiARC), an organic planarization layer (OPL), and/or other suitable masking materials used in semiconductor fabrication to define specific areas for etching or deposition processes. After removing the block mask, the (patterned) dielectric cap layer 402 is utilized to etch the substrate 102, exposing the surface of the source/drain region 150 and resulting in contact trench 502.

The contact trench 502 formed in the substrate 102 has a second width W2 in the x-axis, and the width W2 is beneficially larger than source/drain width W1, which allows for forming a thicker epitaxial liner. Vertical sidewalls 512 and horizontal surfaces 510 of the contact trench 502 may have different crystallographic orientations. For example, the horizontal surfaces 510 may have a first crystalline orientation <100>, while the vertical sidewalls 512 may have a second crystalline orientation <110>.

According to one or more embodiments, the present disclosure provides example techniques of forming epitaxial material in the contact trench 502. The example techniques of forming the epitaxial material in the contact trench 502 are BEOL-compatible thermal steps in which their thermal budget, which includes temperature and duration, does not result in frontside interconnect degradation. In the context of semiconductor manufacturing, the thermal budget refers to the total amount of thermal energy, in terms of temperature and time, that a semiconductor wafer can be exposed to during processing without adversely affecting the device’s performance or integrity. Excessive heat can lead to issues such as dopant diffusion, degradation of materials, and damage to sensitive structures like interconnects. The thermal budget is managed to ensure that the thermal processes, such as annealing, do not exceed the limits that could compromise the device’s functionality or reliability. For example, for copper-containing interconnects, this thermal budget may be 400-450° Celsius (C) at durations for a few seconds (e.g., less than 10, 15, 20 30 seconds), but could be as high as 1200° C for durations shorter than a microsecond.

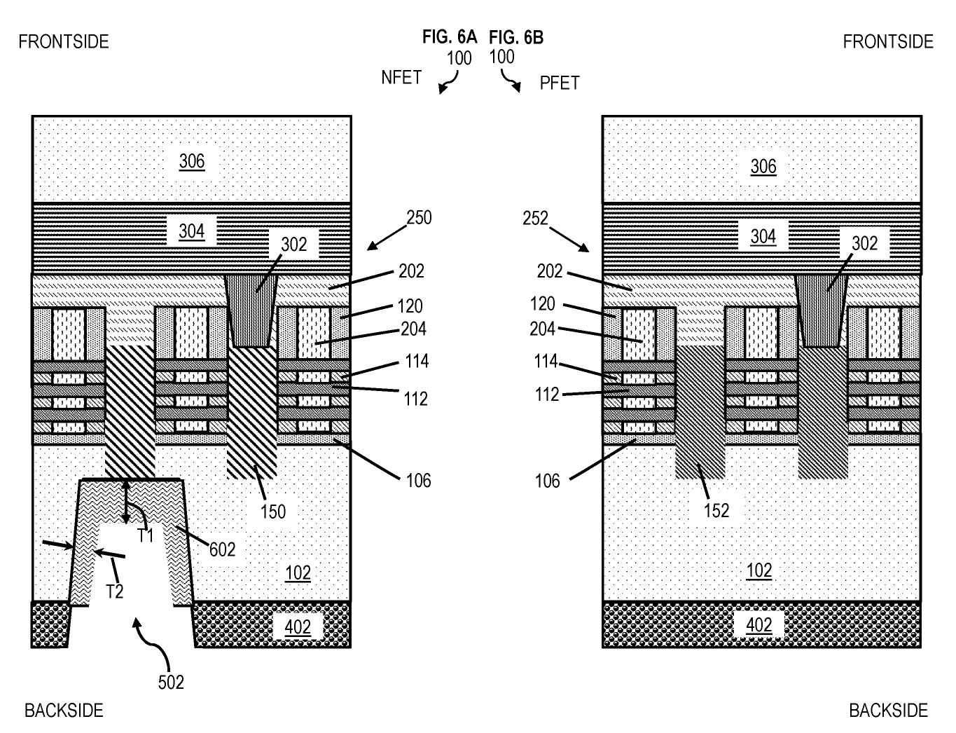

FIGS. 6A and 6B depict the IC 100 after forming an epitaxial liner. FIG. 6A depicts the NFET and FIG. 6B depicts the PFET. While the PFET side is protected, an epitaxial liner 602 is formed in the contact trench 502. The epitaxial liner 602 is formed by low-temperature selective epitaxial growth from the (underlying) substrate 102. The epitaxial liner 602 can be silicon formed with n-type dopants such as, for example, silicon doped with phosphorous (Si:P).

For growth of the epitaxial liner 602, the low-temperature epitaxial growth, with a temperature less than about 450°C and preferably (but not a necessity) less 400°C, is optimized to increase the active concentration of n-type dopants to the range of above 7x10²⁰ cm⁻³, preferably (but not a necessity) above 1x10²¹ cm⁻³ with the corresponding chemical concentration of n-type dopants above 1x10²¹ cm⁻³ and preferably (but not a necessity) above 1.5x10²¹ cm⁻³.

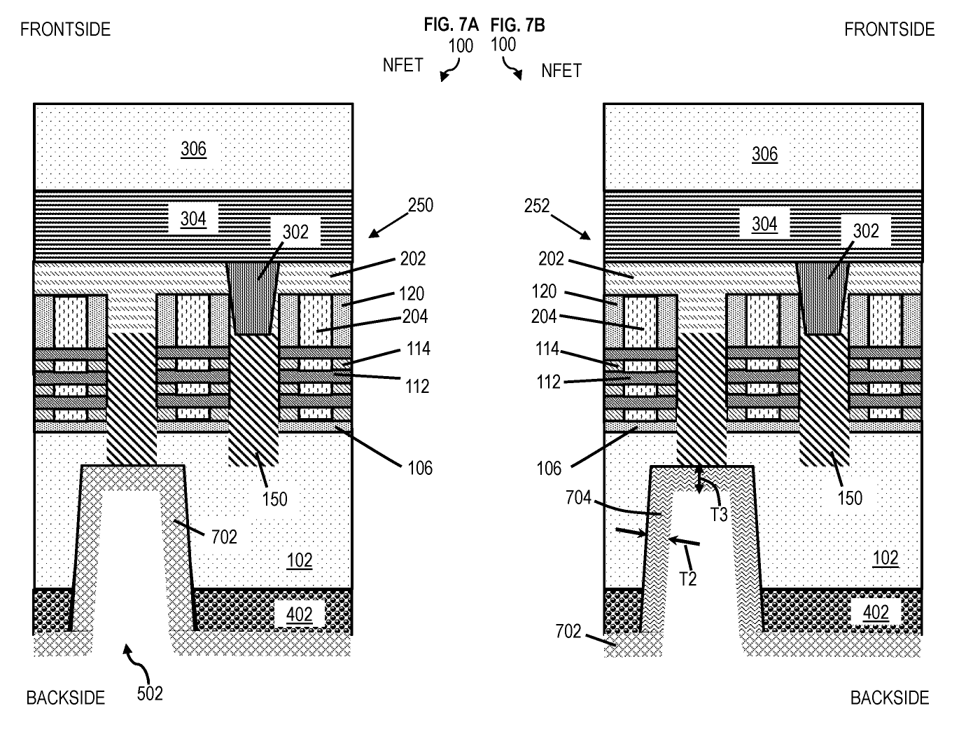

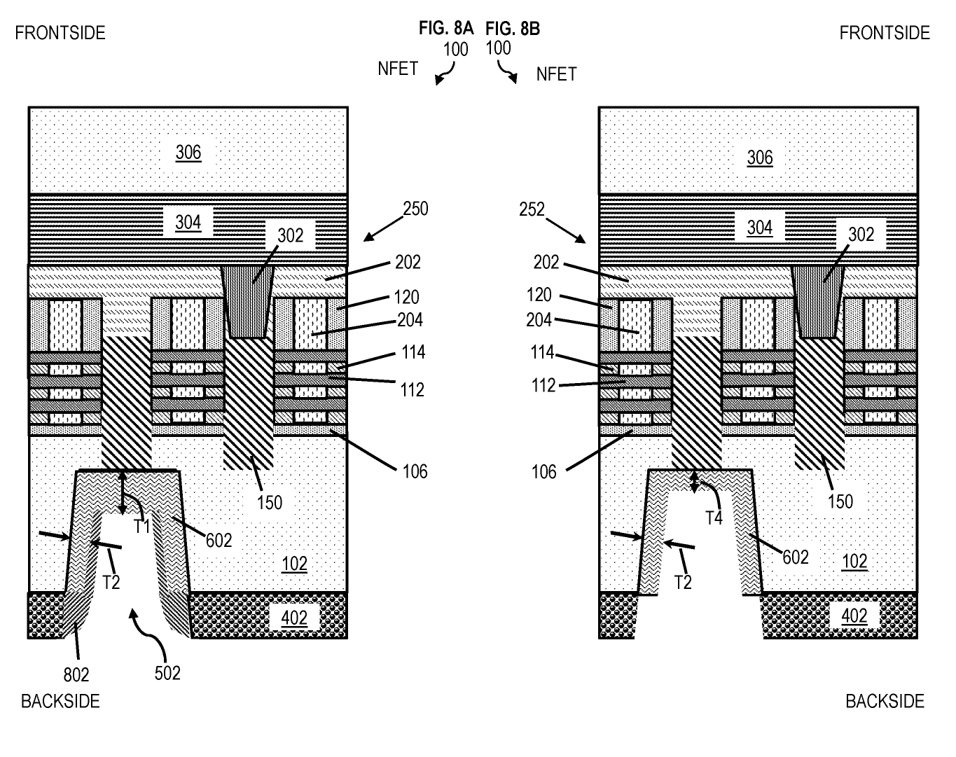

Epitaxial material can grow faster on <100> crystalline planes than on <110> crystalline planes resulting in the sidewall thickness T2 being thinner than top thickness T1 of the epitaxial liner 602. BEOL-compatible, short-duration, high-temperature anneals can be conducted after epitaxial growth of the epitaxial liner 602 to further activate n-type dopants. In one or more embodiments, the current crowding effect requires a minimum sidewall thickness T2 to extract any contact resistance benefit discussed further below. Excessive horizontal top thickness T1 introduces an additional series resistance, which is not desirable. Accordingly, a conformal epitaxial liner is desirable with a thickness T1 approximately the same thickness T2. Furthermore, the epitaxial liner with an inverted thickness ratio where top thickness T1 is less than thickness T2 is desirable. Example techniques of forming an epitaxial liner with a thinner top thickness are discussed below in FIGS. 7A, 7B, 8A, and 8B.

FIGS. 7A and 7B depict the IC 100 after forming an epitaxial liner with a different technique of low-temperature conformal deposition and short-duration high-temperature anneal. FIGS. 7A and 7B illustrate stages of fabricating the epitaxial liner for the NFET, which apply by analogy to the PFET but not shown for conciseness. FIG. 7A depicts a film 702 formed in the contact trench 502. For the NFET example, the film 702 is formed by low-temperature conformal deposition to form amorphous silicon. The amorphous silicon of the film 702 can be amorphous silicon formed with n-type dopants such as, for example, silicon doped with phosphorous (Si:P). Low-temperature conformal deposition of the doped Si:P film can be conducted without much epitaxial templating from the adjacent crystalline of the underlying substrate, and the film growth rate does not depend on underlying crystal planes/orientations. This means that the top thickness and the side thickness are about equal.

In the next stage of FIG. 7B, the (amorphous) film 702 is converted to an epitaxial layer 704 as a crystallized film with Si:P via an epitaxial regrowth anneal. BEOL-compatible, short-duration, high-temperature anneals can be conducted to convert the (doped) film 702 into a crystalline epitaxial film (e.g., epitaxial layer 704) via the epitaxial regrowth process. The epitaxial regrowth process can further activate n-type dopants to above 1x10²¹ cm⁻³. Accordingly, a conformal epitaxial liner with sidewall thickness T1 approximately equal to the top thickness T3 has been realized, after converting the film 702 to the epitaxial layer 704. Amorphous or defective crystalline material that forms inadvertently on the dielectric cap layer 402 (e.g., hard mask layer) can be removed by metal CMP processes.

FIGS. 8A and 8B depict the IC 100 after forming an epitaxial liner and adjusting the top thickness to sidewall thickness ratio using a sacrificial spacer. This is another technique. FIGS. 8A and 8B illustrate stages of fabricating the epitaxial liner for the NFET, which apply by analogy to the PFET but not shown for conciseness. After the processes of FIGS. 6A and 6B, FIGS. 8A and 8B represent fabrication processes of the NFET to adjust the top thickness of epitaxial liner 602. As seen in FIG. 8A, a sacrificial spacer 802 is formed to protect the sidewall portion of the epitaxial liner 602 and expose the horizontal portion of the epitaxial liner 602. The sacrificial spacer 802 can be an oxide material, such as silicon dioxide, etc.

While protecting the sidewall portion of the epitaxial liner 602 with the sacrificial spacer 802, etching is performed to recess the horizontal portion of the epitaxial liner 602 as seen in FIG. 8B, thereby reducing the top thickness from thickness T1 to thickness T4 which adjusts the top thickness to sidewall thickness ratio. The sacrificial spacer 802 is selectively removed without etching the epitaxial liner 602 and dielectric cap layer 402 (e.g., hard mask layer, for example, SiN). Accordingly, the epitaxial liner 602 now has a top thickness T4 that is less than the sidewall thickness T2.

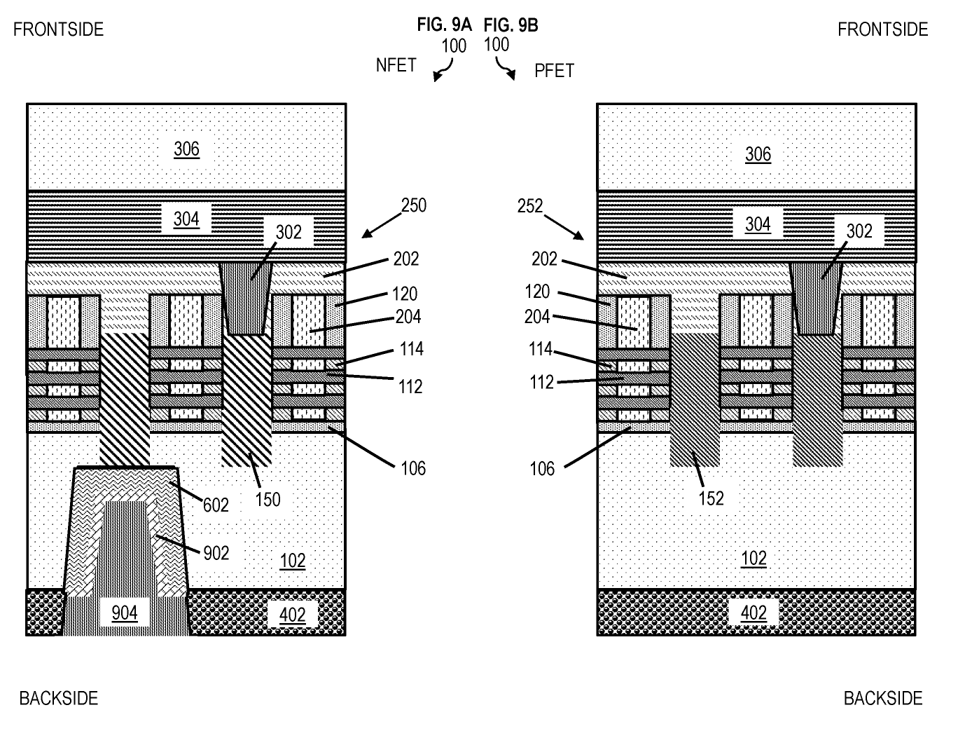

FIGS. 9A and 9B depict the IC 100 after contact metallization with silicide. After using any of the techniques discussed in FIGS. 6A, 6B, 7A, 7B, 8A, and 8B, a metallic liner 902 is deposited using conformal deposition such as conformal vapor deposition (CVD). The metallic liner 902 can include titanium (Ti), thereby forming a silicide such as titanium silicide after annealing. In one or more embodiments, reacting the epitaxial layer 602 with the metallic liner 902 may form silicide or germanosilicide. This step may not require an explicit anneal process as the layers start reacting at 400°C in subsequent processing steps.

Although not shown, an optional conductive diffusion barrier can be formed using CVD on the metallic liner 902, and the optional conductive diffusion barrier may include titanium nitride (e.g. TiN). A conductive material 904 is formed on top of the metallic liner 902 in the contact trench 502, and CMP is performed to remove excess conductive material, which may have been formed on the dielectric cap layer 402. Examples of the conductive material 904 can include metals such as W, Mo, Co, Ru, etc. The conductive material 904 is a source/drain backside contact for the NFET.

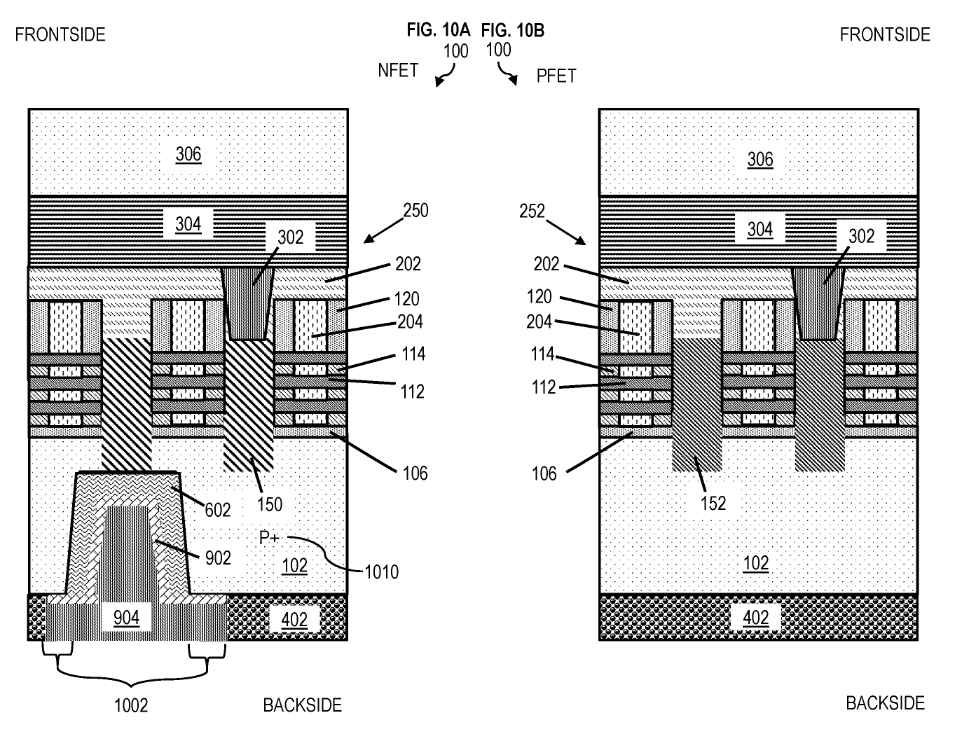

FIGS. 10A and 10B depict the IC 100 after contact metallization, optional well/substrate doping, and optional extended metallization with silicide. In some embodiments, when the substrate 102 has been doped with p-type dopants 1010 (in order to create a well, p-type well, or p-type substrate) at an opposite polarity to the epitaxial liner 602, it can be beneficial to form a simultaneous contact to the substrate 102 and the epitaxial liner 602 as extended conductive material 1002. A portion of the dielectric cap layer 402 (e.g., hard mask layer) can be removed, exposing the p-type substrate/well prior to the metallization sequence. The hard mask removal steps can include additional lithography and reactive ion etching (RIE) steps or can be isotopically etched to expose the substrate/well around the n-type epitaxial layer.

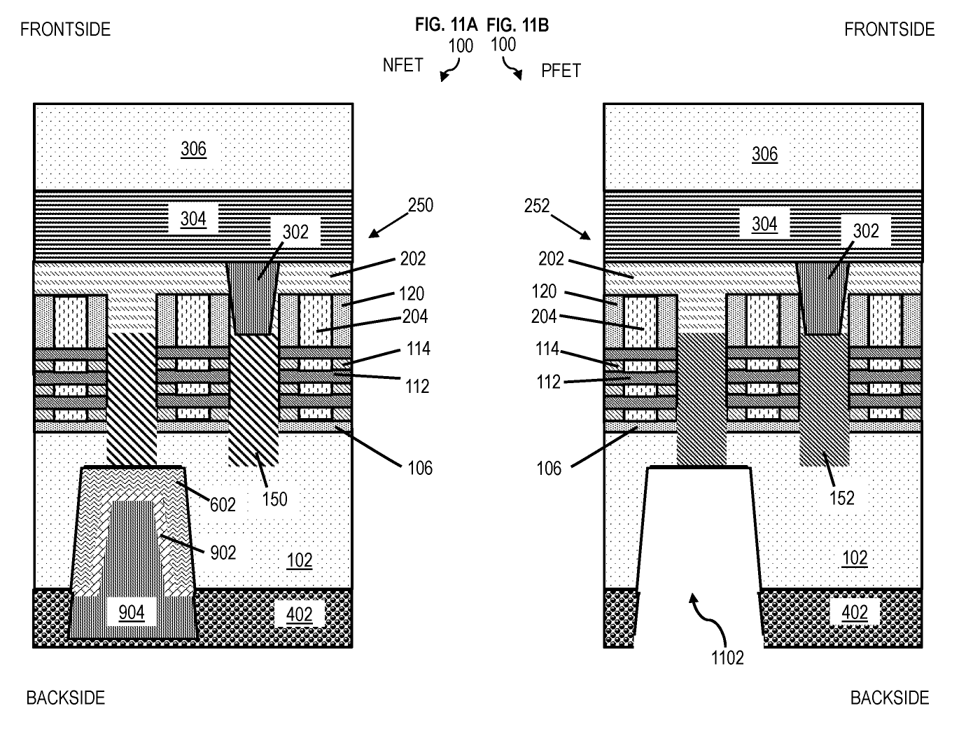

FIGS. 11A and 11B depict the IC 100 after depositing further dielectric cap material and contact patterning. An additional thin layer of dielectric material for the dielectric cap layer 402 is deposited. As noted herein, the thin layer may include SiN or any other suitable material, to protect the backside of the NFET. Lithography is used to perform PFET contact patterning, resulting in contact trench 1102 on the PFET side. The contact trench 1102 is etched to expose the source/drain region 152.

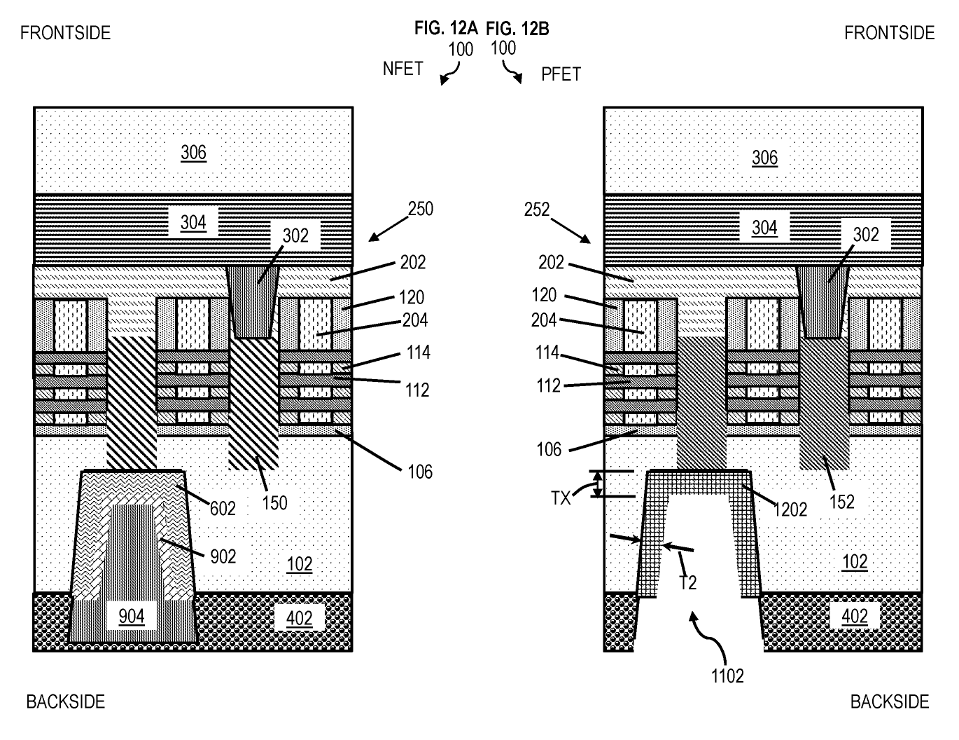

FIGS. 12A and 12B depict the IC 100 after forming an epitaxial liner for the PFET side. While the NFET side is protected, an epitaxial liner 1202 is formed in the contact trench 1102. The epitaxial liner 1202 can be formed by low-temperature selective epitaxial growth from the underlying substrate 102. The epitaxial liner 1202 can be silicon germanium (SiGe) formed with p-type dopants such as, for example, silicon germanium doped with boron (SiGe:B).

For growth of the epitaxial liner 1202, the low-temperature epitaxial growth, with a temperature less than or equal to about 400°C, is optimized to increase the active concentration of p-type dopants to the range of above 7x10²⁰ cm⁻³, preferably (but not a necessity) above 1x10²¹ cm⁻³ with the corresponding chemical concentration of p-type dopants from 8x10²⁰ cm⁻³ and to 3x10²¹ cm⁻³.

Epitaxial material can grow faster on <100> crystalline planes than on <110> crystalline planes resulting in the sidewall thickness T2 being thinner than top thickness TX of the epitaxial liner 1202. In accordance with one or more embodiments, the sidewall thickness T2 to top thickness TX ratio can be adjusted using any of the techniques discussed herein from the (NFET) epitaxial liner 602; this results the top thickness TX being the top thicknesses T3 and T4 based on the technique utilized, as depicted in FIGS. 7A, 7B, 8A, and 8B.

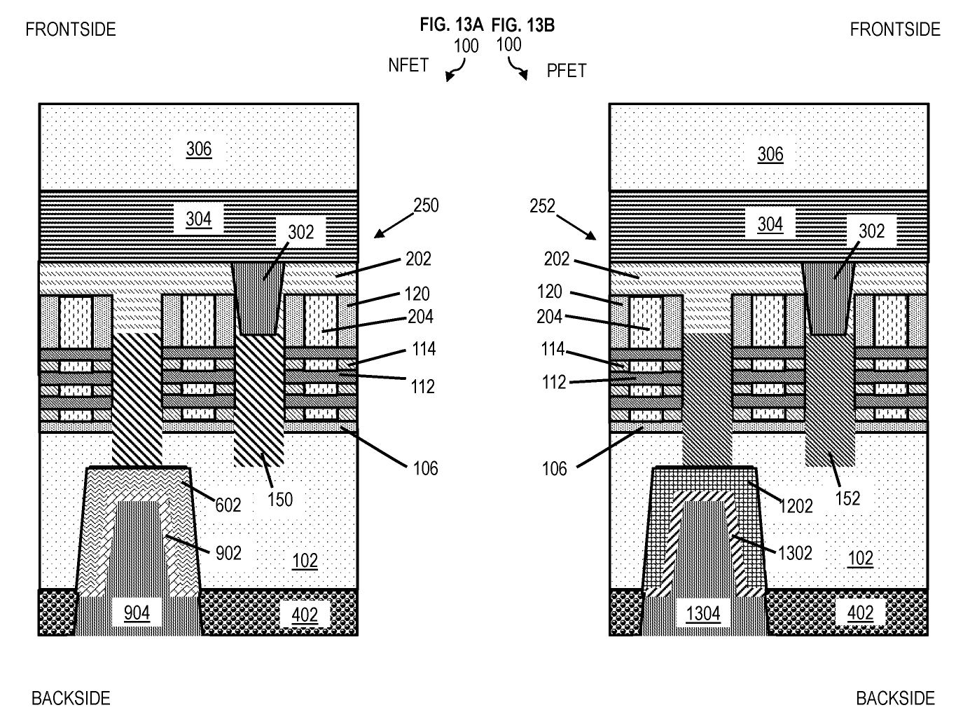

FIGS. 13A and 13B depict the IC 100 after contact metallization with silicide. While the NFET is protected by the additional material of dielectric cap layer 402, a metallic liner 1302 is deposited using conformal deposition. The metallic liner 1302 can include titanium (Ti), nickel (Ni), nickel platinum (NiPt), etc., thereby forming a silicide after annealing. Although Ti may be used, it is noted that a Ni or NiPt silicide provides better contact resistance for the (p-type) epitaxial liner 1202 of the PFET. In one or more embodiments, reacting the epitaxial liner 1202 with the metallic liner 1302 may form a silicide or germanosilicide, and it is noted that formation of the silicide can be completed in subsequent fabrication steps. This silicide step may not require an explicit anneal process as the layers start reacting at 400°C in subsequent processing steps.

Although not shown, an optional conductive diffusion barrier can be formed using CVD, and the optional conductive diffusion barrier may include titanium nitride (e.g. TiN).

A conductive material 1304 is formed on top of the metallic liner 1302 in the contact trench 1102. CMP is performed to remove excess conductive material, which may have been formed on the dielectric cap layer 402, and to open the NFET side thereby exposing the conductive material 1304. Examples of the conductive material 1304 can include metals such as W, Mo, Co, Ru, etc. The conductive material 904 of the NFET and the conductive material 1304 can be referred to as source/drain backside contacts or backside contacts.

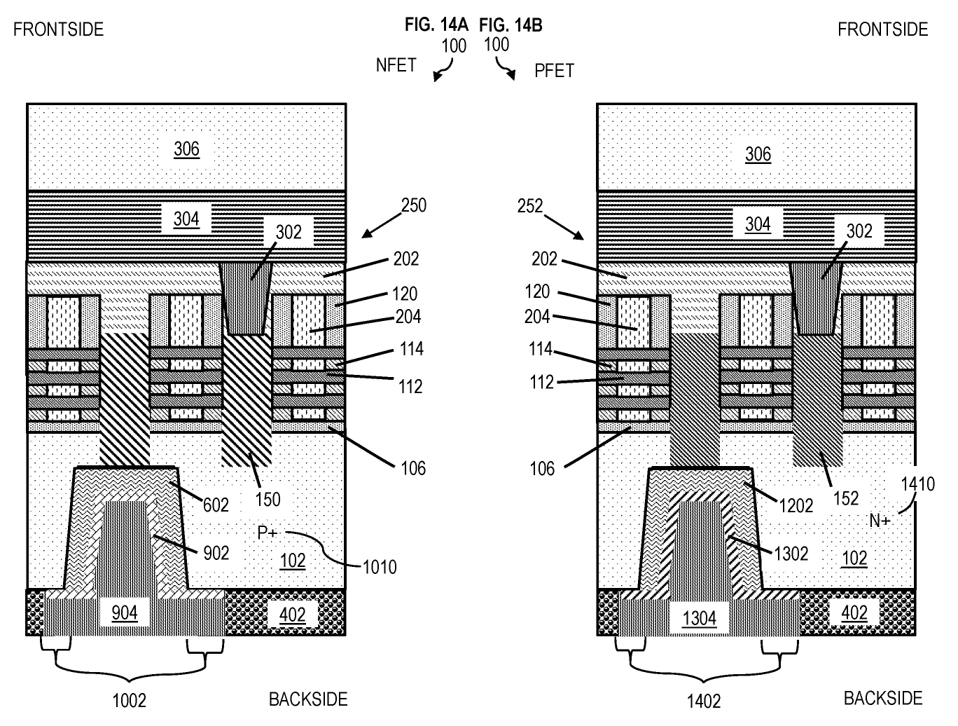

FIGS. 14A and 14B depict the IC 100 after contact metallization, optional well/substrate doping, and optional extended metallization with silicide. The fabrication operations of the PFET are analogous to the NFET described in FIGS. 10A and 10B. In some embodiments, when the substrate 102 has been doped with n-type dopants 1410 (e.g., to create a well, an n-type well, or an n-type substrate) at an opposite polarity to the epitaxial liner 1202, it can be beneficial to form a simultaneous contact to the substrate 102 and the epitaxial liner 1202 as extended conductive material 1402. A portion of the dielectric cap layer 402 (e.g., hard mask layer) can be removed exposing the n-type substrate/well prior to the metallization sequence. The hard mask removal steps can include additional lithography and reactive ion etching (RIE) steps or can be isotopically etched to expose the substrate/well around the n-type epitaxial layer.

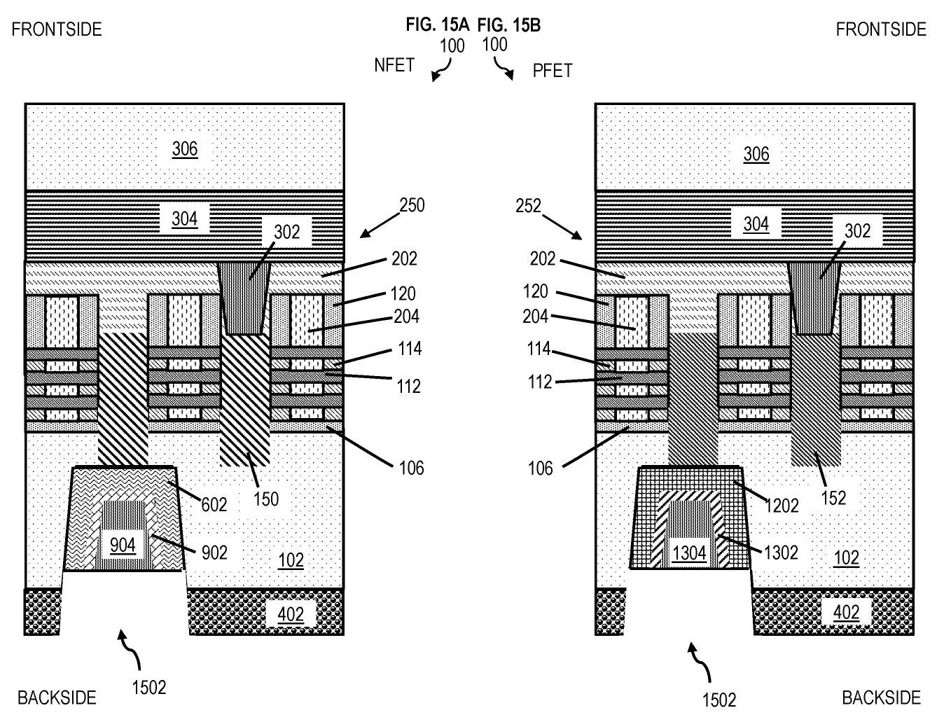

FIGS. 15A and 15B depict the IC 100 after backside contact recess. Etching is performed to recess the conductive materials 904 and 1304 of the source/drain backside contacts, the metallic liner 902, the metallic liner 1302, the epitaxial liner 602, and the epitaxial liner 1202, thereby resulting in trenches 1502.

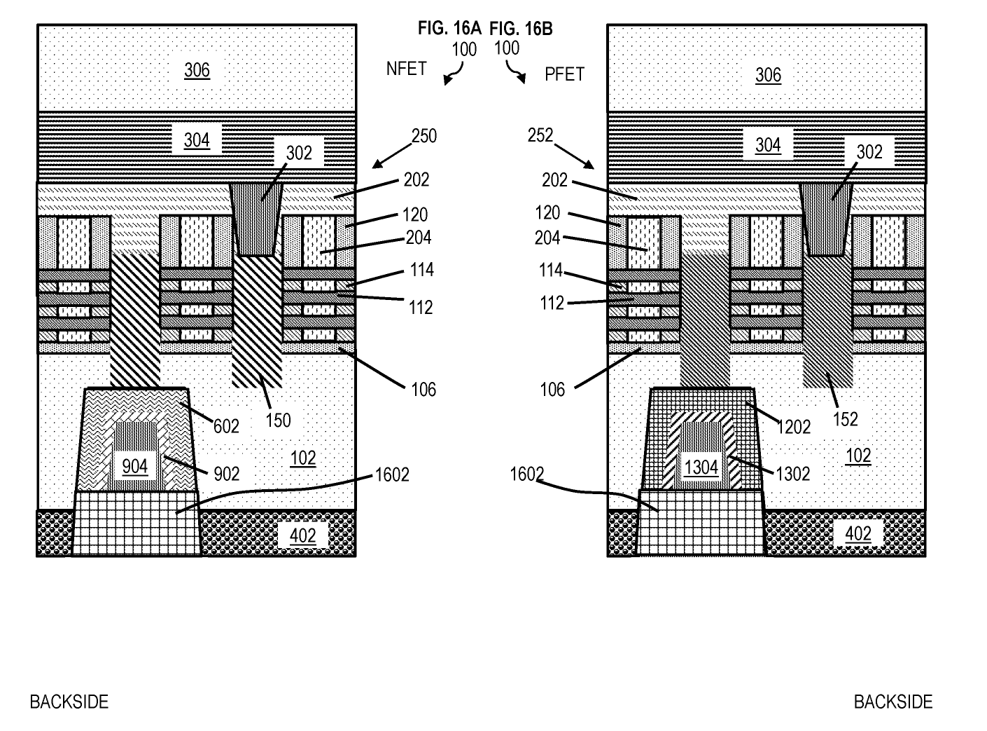

FIGS. 16A and 16B depict the IC 100 after forming a backside contact dielectric cap. Dielectric material is deposited to from a backside contact dielectric cap 1602 in the trenches 1502. The backside contact dielectric cap 1602 covers the conductive materials 904 and 1304, the metallic liners 902 and 1302, and the epitaxial liners 602 and 1202. The dielectric material of the backside contact dielectric cap 1602 is chosen such that the dielectric cap layer 402 can be selectively etched without etching the backside contact dielectric cap 1602. For example, when the dielectric cap layer 402 is silicon nitride, the backside contact dielectric cap 1602 is selected to be a different appropriate dielectric material that is not etched or is resistant to being etched when etching silicon nitride.

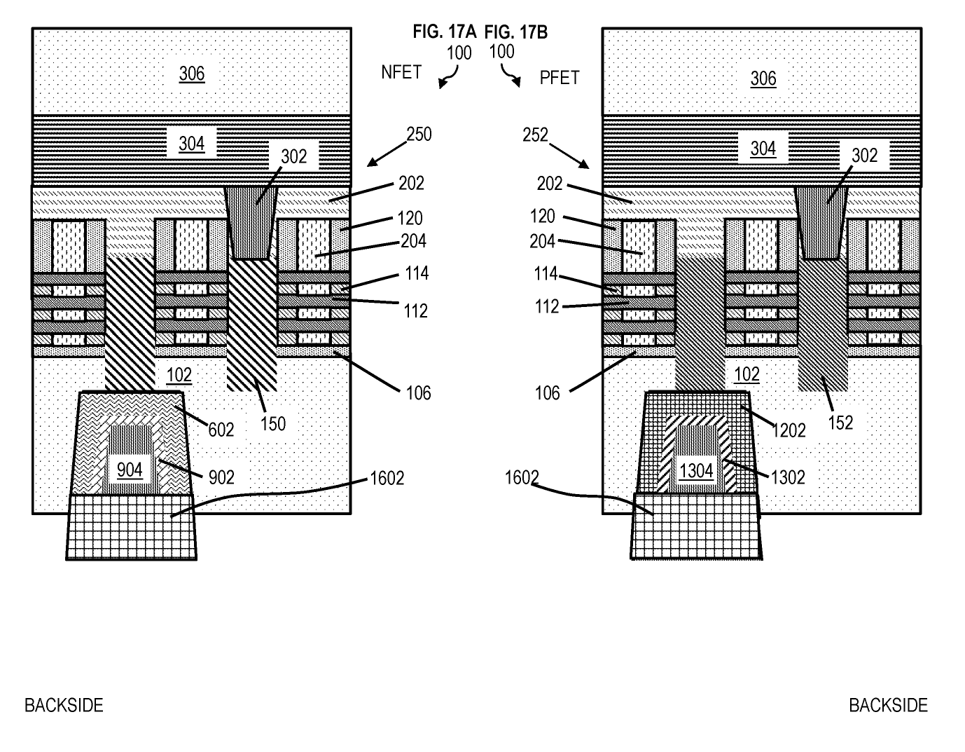

FIGS. 17A and 17B depict the IC 100 after selectively removing the dielectric cap layer. Etching is performed to selectively remove the dielectric cap layer 402, thereby exposing the backside of the substrate 102 in preparation for subsequent etching. This leaves the backside contact dielectric cap 1602 extending beyond the bottom surface of the substrate 102.

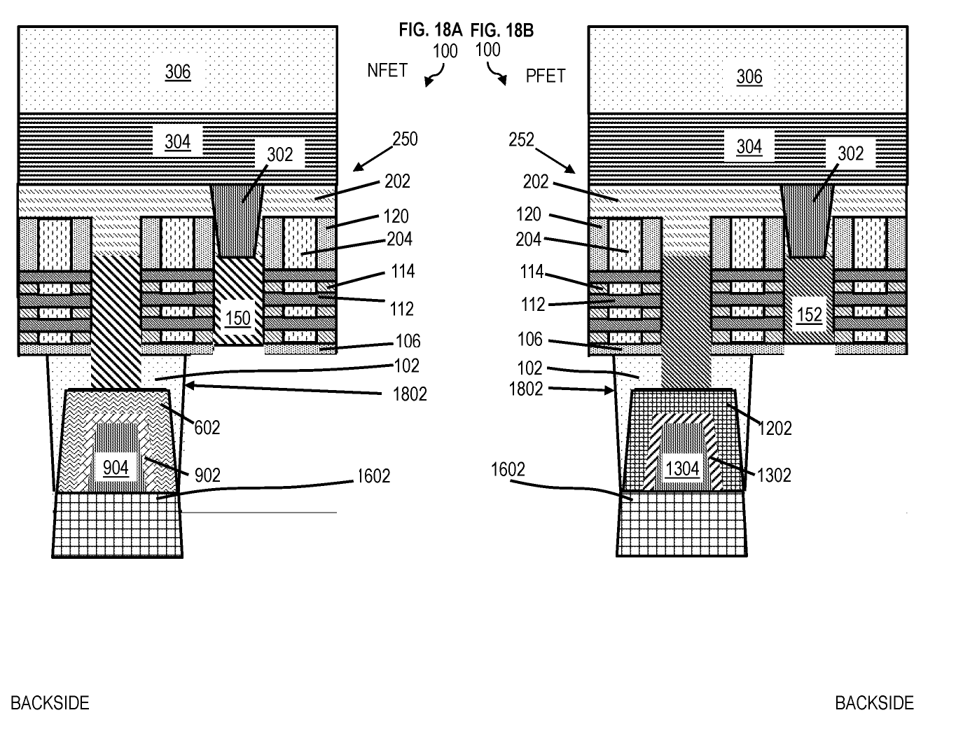

FIGS. 18A and 18B depict the IC 100 after partially recessing the substrate (or well material). The substrate 102 is etched back using the backside contact dielectric cap 1602 as protection, thereby leaving a peripheral substrate 1802 remaining on the sides of the epitaxial liners 602 and 1202 and the source/drain regions 150 and 152. A directional etch, such as reactive ion etching, can be utilized. In addition to forming the peripheral substrate 1802, exposed portions of the source/drain regions 150 and 152 are etched back from the backside. This leaves one of the source/drain regions 150 extending down beyond the bottom dielectric isolation layer 106 while the other does not. Similarly, one of the source/drain regions 152 extends down beyond the bottom dielectric isolation layer 106 while the other does not.

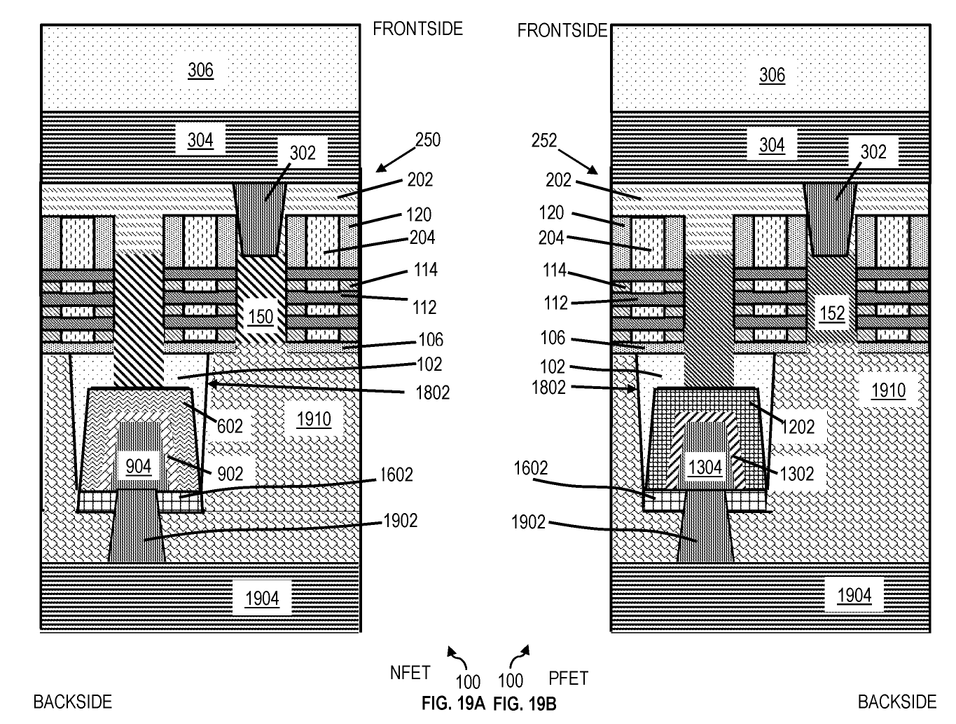

FIGS. 19A and 19B depict the IC 100 after forming the backside interconnect layer. Backside ILD material is deposited forming a backside ILD 1910. Planarization/polishing can be performed, for example, by CMP, to make the backside contact dielectric cap 1602 and the backside ILD 1910 coplanar. Additional backside ILD material is then deposited, and openings for metal contacts are patterned in the backside ILD 1910 and backside contact dielectric cap 1602 to expose bottom surfaces of the conductive materials 904 and 1304 of the source/drain backside contacts. Contact metallization is performed to form metal contacts 1902 to the conductive materials 904 and 1304 of the source/drain backside contacts. Example materials of the metal contacts can include tungsten, titanium, titanium nitride, aluminum, nickel, chromium, copper, gold, etc., along with various combinations and liners. A backside interconnect 1904 is formed on the metal contacts. The backside interconnect 1904 may represent many layers, interconnects, insulating material, etc.

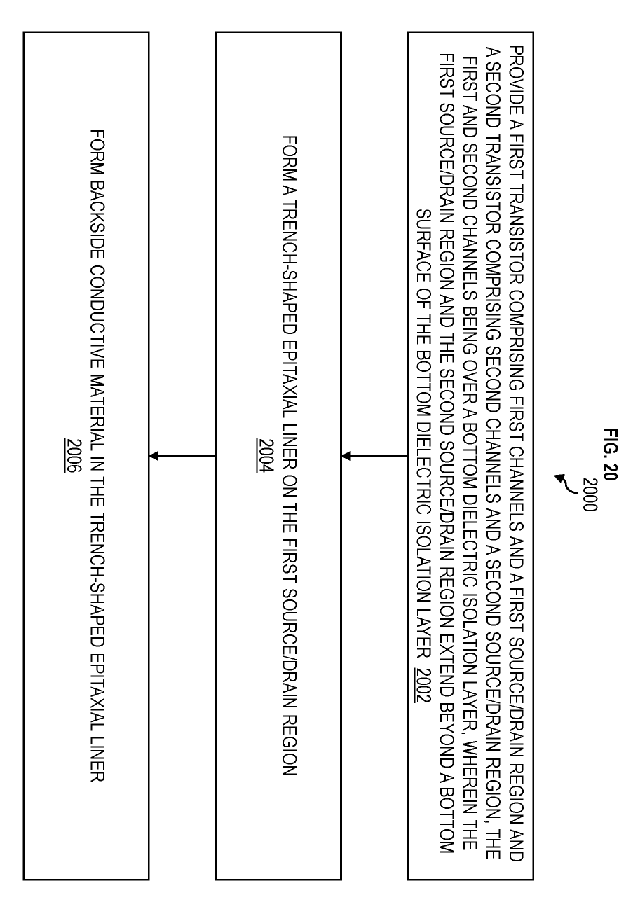

FIG. 20 depicts a flowchart of a method 2000 of forming a semiconductor structure with a low resistance backside contact with a concave epitaxial liner in accordance with one or more embodiments. Reference can be made to any figures discussed herein.

At block 2002, the method 2000 includes providing a first transistor (e.g., transistor 250) comprising first channels (e.g., semiconductor layers 112) and a first source/drain region (e.g., source/drain region 150) and a second transistor (e.g., transistor 252) comprising second channels (e.g., semiconductor layers 112) and a second source/drain region (e.g., source/drain region 152), the first and second channels being over a bottom dielectric isolation layer 106, where the first source/drain region and the second source/drain region extend beyond a bottom surface of the bottom dielectric isolation layer 106.

At block 2004, the method 2000 includes forming a trench-shaped epitaxial liner (e.g., epitaxial liner 602) on the first source/drain region (e.g., source/drain region 150). At block 2006, the method 2000 includes forming backside conductive material (e.g., conductive material 904 as the source/drain backside contact) in the trench-shaped epitaxial liner. The trench-shaped epitaxial liner can be a concave or reverse u-shaped epitaxial formed in the trench.

Further, the first source/drain region (e.g., source/drain region 150) and the trench-shaped epitaxial liner (e.g., epitaxial liner 602) comprise n-type dopants. The trench-shaped epitaxial liner (e.g., epitaxial liner 602) comprises silicon doped with phosphorus. A silicide (e.g., metallic liner 902) intervenes between the trench-shaped epitaxial liner (e.g., epitaxial liner 602) and the backside conductive material (e.g., conductive material 904 as the source/drain backside contact). The silicide is a titanium-based silicide.

The method further includes forming another trench-shaped epitaxial liner (e.g., epitaxial liner 1202) on the second source/drain region (e.g., source/drain region 152); and another backside conductive material (e.g., conductive material 1304 as the source/drain backside contact) in the another trench-shaped epitaxial liner (e.g., epitaxial liner 1202), where the second source/drain region (e.g., source/drain region 152) and the another trench-shaped epitaxial liner (e.g., epitaxial liner 1202) comprise p-type dopants. The another trench-shaped epitaxial liner (e.g., epitaxial liner 1202) comprises silicon germanium doped with boron. A silicide (e.g., metallic liner 1302) intervenes between the another trench-shaped epitaxial liner and the another backside conductive material (e.g., conductive material 1304 as the source/drain backside contact). The silicide (e.g., metallic liner 1302) is a nickel-based silicide or a nickel platinum-based silicide.

A metal contact 1902 is formed on the backside conductive material. A backside contact cap (e.g., backside contact dielectric cap 1602) is formed on the trench-shaped epitaxial liner (e.g., epitaxial liner 602) and the backside conductive material (e.g., conductive material 904 as the source/drain backside contact) and on a side portion of the metal contact 1902. The first source/drain region extends into a peripheral substrate 1802, such that the peripheral substrate 1802 separates the trench-shaped epitaxial liner

As discussed herein, gate material is formed around the semiconductor layers. The gate material includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

Although not shown in detail, contact formation and ILD formation are performed. As such, ILD material can be deposited, source/drain contact openings are patterned by conventional lithography, and then metal is deposited to fill the cavities thereby forming metal contacts. A portion of the metal contacts may include silicide, resulting from the interface of the metal material and semiconductor material. The metal contacts are source/drain contacts that are respectively connected to epitaxial source/drain regions.

The ILD material can be SiO₂, SiN, a low-k dielectric material or an ultra-low-k dielectric material. Low-k dielectric materials may generally include dielectric materials having a k value of about 3.9 or less. The ultra-low-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20◦C). This process generates a volatile etch product that minimizes surface contamination. In another example, cyclic exposure to an oxidant and hexafluoroacetylacetone (Hhfac) at an elevated temperature such as at 275°C can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for the purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagrams or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ± 8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
a first transistor comprising first channels and a first source/drain region and a second transistor comprising second channels and a second source/drain region, the first and second channels being over a bottom dielectric isolation layer, wherein the first source/drain region and the second source/drain region extend beyond a bottom surface of the bottom dielectric isolation layer;
a trench-shaped epitaxial liner formed on the first source/drain region; and
backside conductive material formed in the trench-shaped epitaxial liner.

2. The semiconductor structure of claim 1, wherein the first source/drain region and the trench-shaped epitaxial liner comprise n-type dopants.

3. The semiconductor structure of claim 2, wherein the trench-shaped epitaxial liner comprises silicon doped with phosphorus.

4. The semiconductor structure of claim 2, wherein a silicide intervenes between the trench-shaped epitaxial liner and the backside conductive material.

5. The semiconductor structure of claim 4, wherein the silicide is a titanium-based silicide.

6. The semiconductor structure of claim 1, further comprising another trench-shaped epitaxial liner formed on the second source/drain region; and
another backside conductive material formed in the another trench-shaped epitaxial liner, wherein the second source/drain region and the another trench-shaped epitaxial liner comprise p-type dopants.

7. The semiconductor structure of claim 6, wherein the another trench-shaped epitaxial liner comprises silicon germanium doped with boron.

8. The semiconductor structure of claim 6, wherein a silicide intervenes between the another trench-shaped epitaxial liner and the another backside conductive material.

9. The semiconductor structure of claim 8, wherein the silicide is a nickel-based silicide or a nickel platinum-based silicide.

10. The semiconductor structure of claim 1, further comprising a metal contact formed on the backside conductive material; and
a backside contact cap formed on the trench-shaped epitaxial liner and the backside conductive material and on a side portion of the metal contact, wherein the first source/drain region extends into a peripheral substate, wherein the peripheral substrate separates the trench-shaped epitaxial liner from the bottom dielectric isolation layer.

11. A method comprising:
providing a first transistor comprising first channels and a first source/drain region and a second transistor comprising second channels and a second source/drain region, the first and second channels being over a bottom dielectric isolation layer, wherein the first source/drain region and the second source/drain region extend beyond a bottom surface of the bottom dielectric isolation layer;
forming a trench-shaped epitaxial liner on the first source/drain region; and
forming backside conductive material in the trench-shaped epitaxial liner.

12. The method of claim 11, wherein the first source/drain region and the trench-shaped epitaxial liner comprise n-type dopants.

13. The method of claim 12, wherein the trench-shaped epitaxial liner comprises silicon doped with phosphorus.

14. The method of claim 12, wherein a silicide intervenes between the trench-shaped epitaxial liner and the backside conductive material.

15. The method of claim 14, wherein the silicide is a titanium-based silicide.

16. The method of claim 11, further comprising forming another trench-shaped epitaxial liner on the second source/drain region; and
another backside conductive material in the another trench-shaped epitaxial liner, wherein the second source/drain region and the another trench-shaped epitaxial liner comprise p-type dopants.

17. The method of claim 16, wherein the another trench-shaped epitaxial liner comprises silicon germanium doped with boron.

18. The method of claim 16, wherein:
a silicide intervenes between the another trench-shaped epitaxial liner and the another backside conductive material; and
the silicide is a nickel-based silicide or a nickel platinum-based silicide.

19. The method of claim 11, wherein:
a metal contact is formed on the backside conductive material;
a backside contact cap is formed on the trench-shaped epitaxial liner and the backside conductive material and on a side portion of the metal contact; and
the first source/drain region extends into a peripheral substate, such that the peripheral substrate separates the trench-shaped epitaxial liner from the bottom dielectric isolation layer.

20. A semiconductor structure comprising:
an n-type transistor (NFET) comprising first channels and a first source/drain region and a p-type transistor (PFET) comprising second channels and a second source/drain region, the first and second channels being over a bottom dielectric isolation layer, wherein the first source/drain region and the second source/drain region extend beyond a bottom surface of the bottom dielectric isolation layer;
a first backside conductive material formed in an n-type trench-shaped epitaxial liner, the n-type trench-shaped epitaxial liner being formed on the first source/drain region; and
a second backside conductive material formed in a p-type trench-shaped epitaxial liner, the p-type trench-shaped epitaxial liner being formed on the second source/drain region.
